(19) United States
(12) Patent Application Publication
(10) Pub. No.: US 2007/0105362 A1
(43) Pub. Date: May 10, 2007

(54) Methods of forming contact structures in low-k materials using dual damascene processes

(76) Inventors: Jae Hak Kim, Fishkill, NY (US); Wan Jae Park, Fishkill, NY (US); Yi-Hsiung Lin, Poughkeepsie, NY (US)

Correspondence Address: MYERS BIGEL SIBLEY & SAJOVEC, PO BOX 37428, RALEIGH, NC, 27627, US

(21) Appl. No.: 11/270,783

(22) Filed: Nov. 9, 2005

(51) Int. Cl. H01L 21/4763

(52) U.S. Cl. 438/618

(57) ABSTRACT

A method of forming a via using a dual damascene process can include removing a material from a recess in a low-k material using an ashing process while maintaining a protective spacer on an entire side wall of the recess to cover the low-k material in the recess.

### FIELD OF THE INVENTION

The present invention relates to methods of forming structures in integrated circuits, and more particularly, to methods of forming structures in integrated circuits using dual damascene processes.

### BACKGROUND

The use of copper as a material for interconnection in integrated circuits offers some advantages such as lower resistivity, reduction in the number of metal layers used in the integrated circuit, and/or better reliability compared to other types of metals such as aluminum or aluminum alloys. For example, FIG. 1 is a graph that illustrates exemplary gate delays in integrated circuits as well as typical interconnect delays provided by different materials. As shown in FIG. 1, the use of copper can provide relatively low interconnect delay relative to other types of interconnect materials.

However, use of copper as interconnect in integrated circuits can be complicated when formed via conventional dry etching as illustrated, for example, in FIG. 2A, where photoresist is formed on a metal layer and etched to provide the interconnect shown in FIG. 2B. In contrast, damascene processing using copper can be provided according to FIGS. 3A-3C. According to FIGS. 3A-3C, a substrate is etched to provide trenches therein and then copper is deposited on the substrate so as to overfill the trenches. The excess copper is then subjected to chemical mechanical polishing (CMP) to provide the copper interconnect shown in FIG. 3C.

The use of copper as interconnect may call for improved diffusion barrier layers to be used therewith as well as raise the likelihood that copper may contaminate other steps used to fabricate the integrated circuits.

A conventional single damascene process using copper for interconnect is shown in FIGS. 4A-4D. According to FIG. 4A, a substrate 400 includes a lower level of metal interconnect 405 and a via 410 that allows electrical contact between an overlying structure and the metal interconnect 405. As shown in FIG. 4B, copper can be deposited in the via 410. As shown in FIG. 4C, a trench 415 can be formed above the via 410 which can be formed using conventional photolithographic and etching techniques. As shown in FIG. 4D, copper is again deposited in the metal trench 415 on the via 410 to complete a structure 420 that provides electrical contact between an overlying structure and the lower level of metal interconnect 405. As shown in FIGS. 4A-4D, the via 410 and the trench 415 can be filled separately with copper according to separate single damascene fabrication steps.

It is also known to use a dual damascene process to fabricate structures such as those shown above in FIGS. 4A-4D. In particular, FIGS. 5A-5E show a conventional dual damascene process that is commonly referred to as trench first dual damascene. According to FIG. 5A, a photoresist material 505 is deposited on an upper layer 510 which is on a lower layer 515 having a first etch stop layer 520 therebetween. A second etch stop layer 525 is located between the lower layer 515 and a substrate 530 including a lower copper interconnect 535.

According to FIG. 5B, the photoresist 505 is used to pattern and etch the upper layer 510 to form a trench 540 that exposes the first etch stop layer 520, whereafter the photoresist 505 is removed. According to FIG. 5C, a second photoresist material 545 is deposited in the trench 540 to define an opening 547 therein through which the lower layer 515 is patterned to form a lower via portion 550 in the trench 540 that exposes the second etch stop layer 525. According to FIG. 5D, the second etch stop layer 525 is removed.

As shown in FIG. 5E, the second photoresist material is removed to define the opening in which copper may be deposited in the via portion 550 and the trench 540 to complete the desired structure. As is well known, however, one of the drawbacks with the “trench first” approach is that if the second photoresist material used to form the lower via portion 550 is misaligned in the trench 540 relative to the copper interconnect 535, the overall size of the via through which an electrical connection may be provided to the lower copper interconnect 535 may be reduced.

It is also known to use what is commonly referred to as a “via first” dual damascene process to create the contact structures described above. As shown in FIG. 6A-6E, a contact structure can be formed by first forming a via as part of the lower structure followed by a trench as an upper part of the structure. According to FIG. 6A, a photoresist 605 is formed on an upper layer 610. A first etch stop layer 620 is formed between the upper layer 610 and a lower layer 615. A second etch stop layer 625 is formed between the lower layer 615 and a copper interconnect 635 in a substrate 630.

As shown in FIG. 6B, a via portion of the contact structure 650 is etched using the photoresist 605 as a mask and a second photoresist 645 is formed on the upper layer 610 to expose the via 650 as shown in FIG. 6C. According to FIG. 6D, the second photoresist 645 is used as an etch mask to form the trench 640 as part of the contact structure on the via 650 to provide the contact structure shown in FIG. 6E. In contrast to the “trench first” dual damascene structure discussed above in reference to FIGS. 5A-5E, misalignment of the trench 640 formed on the via 650 according to the “via first” dual damascene process may allow for misalignment of the trench 640 while still maintaining the overall size of the via 650. Accordingly, the “via first” dual damascene process is sometimes preferred over the “trench first” dual damascene process discussed above.

Dual damascene processes are also discussed, for example, in Korean Patent Application Number KR2004-0058955, U.S. Pat. No. 6,743,713, and U.S. Pat. No. 6,057,239.

### SUMMARY

Embodiments according to the invention can provide methods of forming contact structures in low-k materials using dual damascene processes. Pursuant to these embodiments, a method of forming a via using a dual damascene process can include removing a material from a recess in a low-k material using an ashing process while maintaining a protective spacer on an entire side wall of the recess to cover the low-k material in the recess.

In some embodiments according to the invention, removing a material includes removing a sacrificial material from the recess. In some embodiments according to the invention, removing a material further includes removing a photo-resist material from around the recess along with removing the sacrificial material from inside the recess. In some embodiments according to the invention, the photo-resist material and the sacrificial material comprise a common material. In some embodiments according to the invention, the photo-resist material and the sacrificial material are an organic polymer. In some embodiments according to the invention, the protective spacer is silicon oxide. In some embodiments according to the invention, the low-k material is porous SiCOH.

In some embodiments according to the invention, removing a material from a recess further includes etching the material using an etchant to expose the protective spacer inside the recess. In some embodiments according to the invention, etching further includes etching the material using O₂ and CO₂, N₂ and H₂, NH₃ and O₂, NH₃ and N₂, or NH₃ and H₂. In some embodiments according to the invention, etching is carried out at a pressure of about 10 to about 700 Mtorr.

In some embodiments according to the invention, the method further includes forming a trench over the recess and removing the protective spacer from the side wall. The recess and the trench are filled with copper.

In some embodiments according to the invention, a method of forming a via using a dual damascene process includes removing a sacrificial material from a low-k material having a recess therein with a protective side wall spacer and then forming a trench over the recess. The side wall spacer is then removed. In some embodiments according to the invention, the protective side wall spacer is silicon oxide. In some embodiments according to the invention, the low-k material is porous SiCOH.

In some embodiments according to the invention, a method of forming a via using a dual damascene process includes forming a hard mask material on a low-k material. A via is formed in the low-k material through the hard mask material. A protective side wall spacer is formed on a side wall of the via and on the hard mask material, wherein the protective side wall spacer has an etch selectivity relative to the hard mask material. A sacrificial material is formed in the via on the protective side wall. A photo-resist material is formed on the hard mask material including an opening therein over the via. The photo-resist material and the sacrificial material are removed from inside the via while avoiding removing the protective side wall spacer from inside the via. A trench is formed over the via while maintaining a lower portion of the via having the protective side wall spacer thereon. The protective side wall spacer is removed from the lower portion of the via. The via and the trench are filled with copper.

In some embodiments according to the invention, forming a trench over the via includes etching the hard mask material to remove the hard mask material from an upper surface of the low-k material and a portion of the low-k material beneath the upper surface to form the trench in the low-k material while maintaining the protective spacer on a lower portion of the via. In some embodiments according to the invention, the protective side wall spacer is silicon oxide. In some embodiments according to the invention, the low-k material is porous SiCOH.

In some embodiments according to the invention, a method of forming contact structures using a via-first dual damascene process includes maintaining a protective spacer on an entire side wall of a recess in an low-k material during removal of a sacrificial material inside the recess. In some embodiments according to the invention, the protective spacer is silicon oxide. In some embodiments according to the invention, the low-k material is porous SiCOH.

### BRIEF DESCRIPTION OF THE DRAWINGS

FIG. 1 is a graph that illustrates exemplary gate delays in integrated circuits as well as typical interconnect delays provided by different materials.

FIGS. 2A-2B are cross sectional views that illustrate the formation of a via using conventional dry etching.

FIGS. 3A-3C are cross sectional views that illustrate conventional damascene processing.

FIGS. 4A-4D are cross sectional views that illustrate conventional single damascene processing.

FIGS. 5A-5E are cross sectional views that illustrate conventional “trench first” dual damascene processing.

FIGS. 6A-6E are cross sectional views that illustrate conventional “via first” dual damascene processing.

FIGS. 7A-7L are cross sectional views that illustrate the formation of contact structures using a dual damascene process according to some embodiments of the invention.

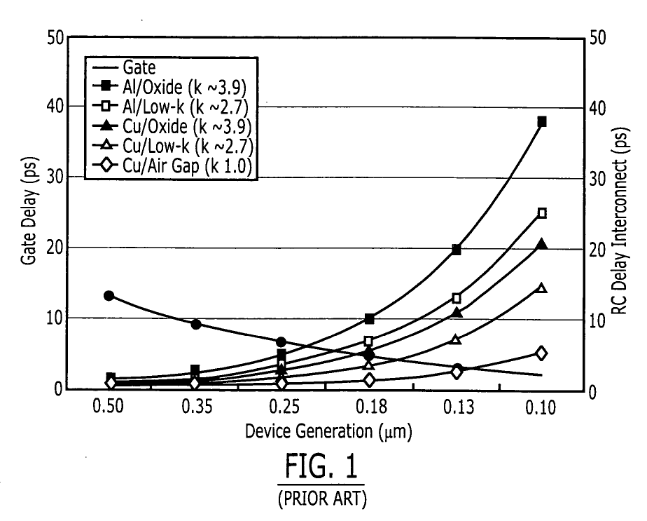

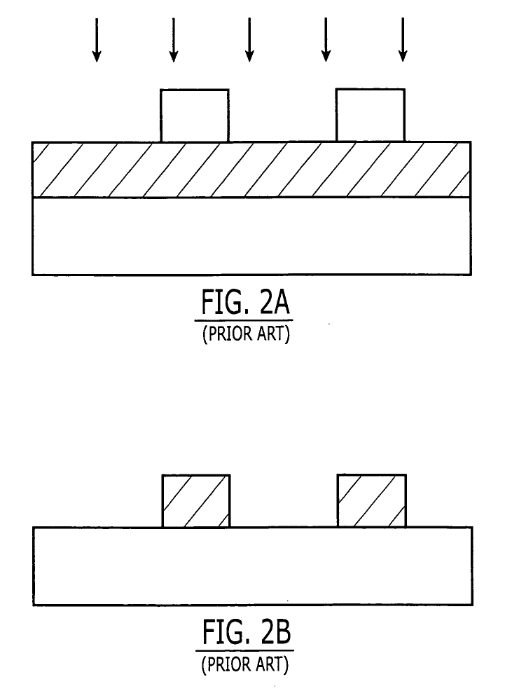

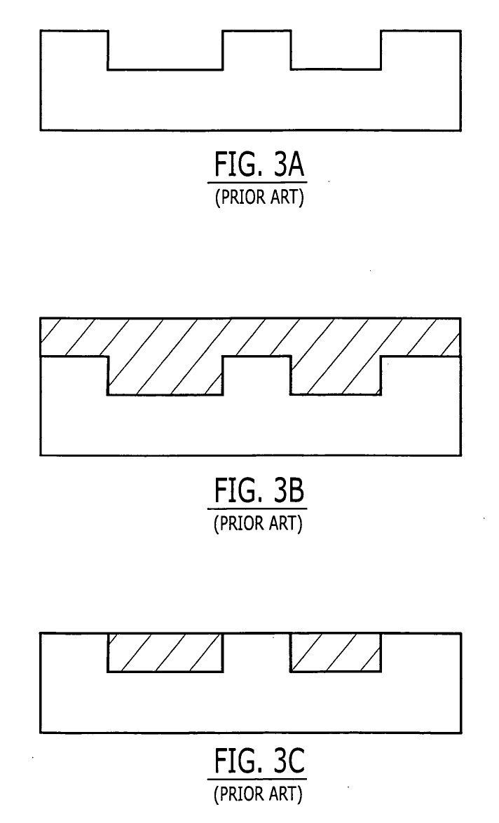

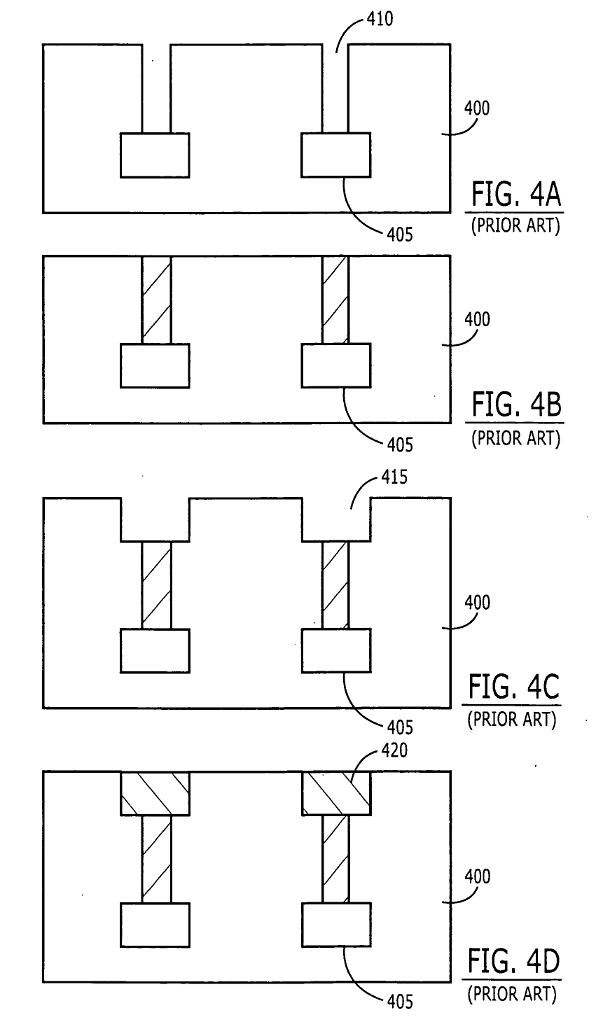

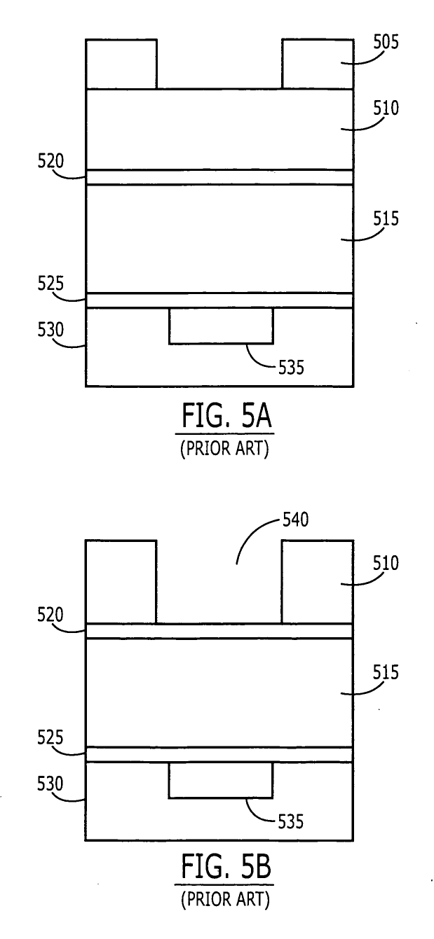

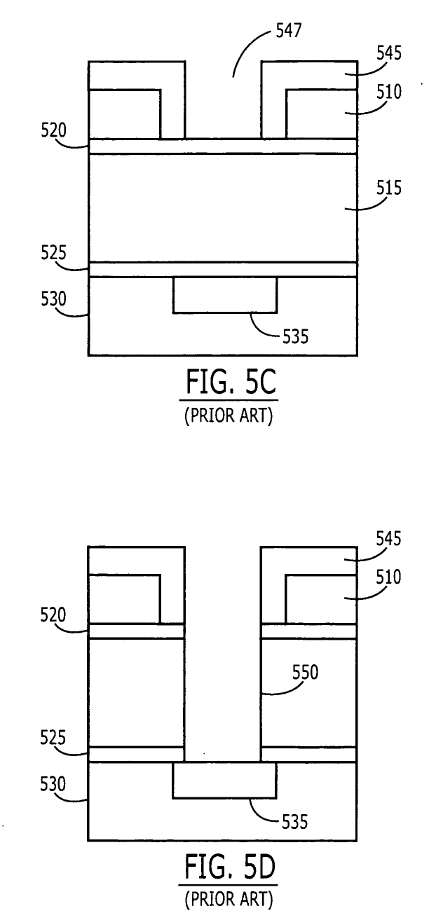

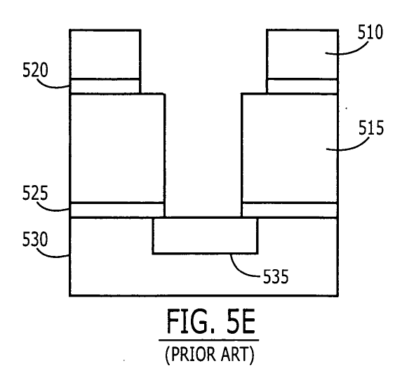

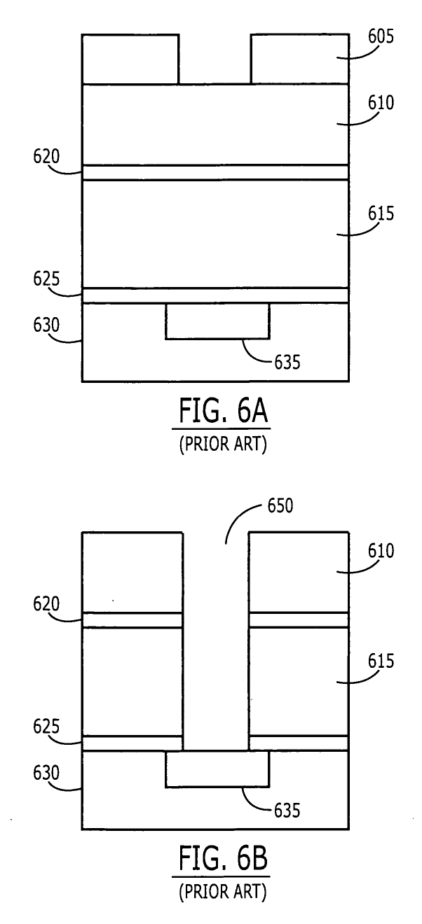

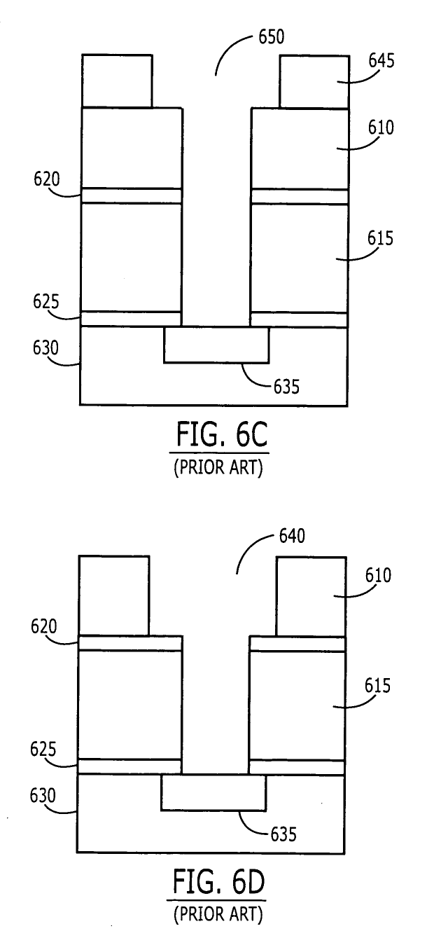

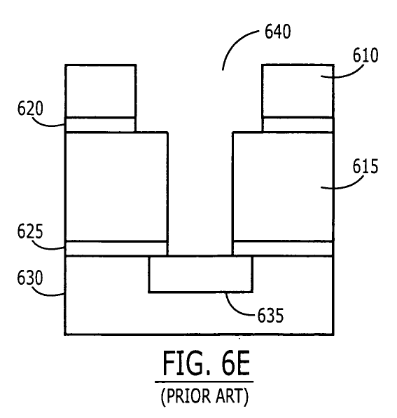

### DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In some embodiments according to the invention, a protective side wall spacer that is formed in a recess in a low-k material is maintained while a material (such as a photoresist and/or a sacrificial material in the recess) is removed. The removal of the photoresist and/or sacrificial material can be performed by an ashing process whereby the low-k material may be damaged if the protective side wall spacer is not maintained in the recess. As described herein in greater detail, the recess can provide the lower portion of a “via first” contact structure formed using a dual damascene process. Accordingly, in some embodiments according to the invention, a trench can be formed to provide an upper part of the contact structure in the “via first” dual damascene process. The trench can be formed by using remnants of the protective spacer that are outside the recess as an etching mask. Accordingly, in some embodiments according to the invention, the material removed by an ashing process can be removed prior to formation of the trench thereby allowing the low-k material to be protected by the protective side wall spacer during the removal of the material in the ashing process (e.g., photoresist and/or sacrificial material in the via). As used herein, the term “ashing” refers to the removal of materials, such as photoresist materials, from semiconductor substrates using plasma or ultraviolet light generated ozone.

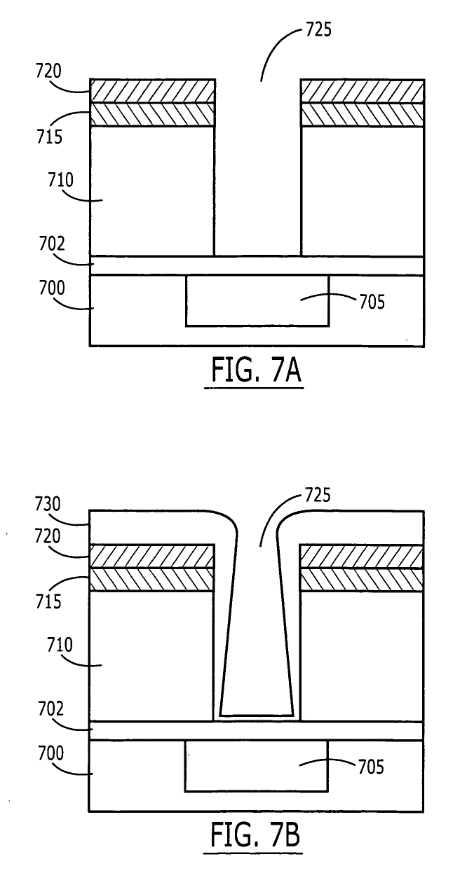

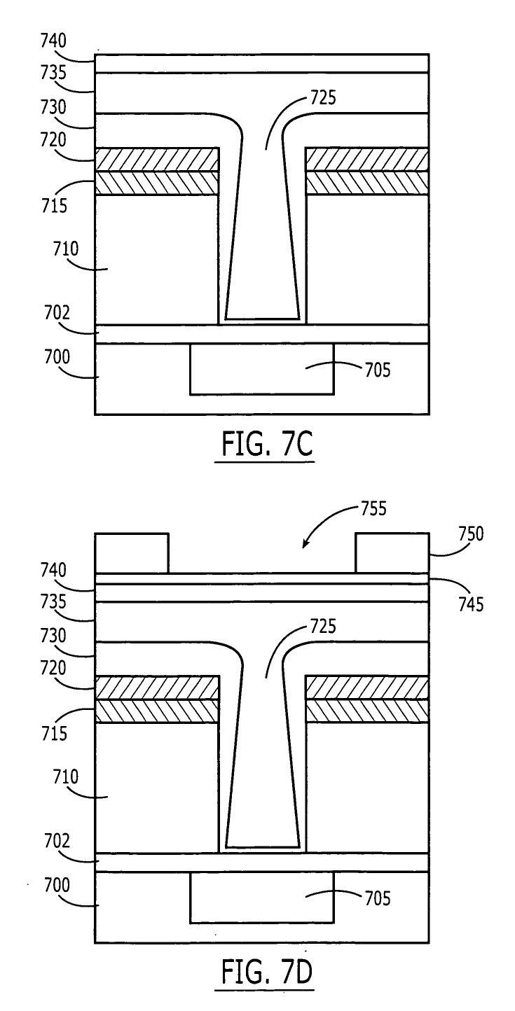

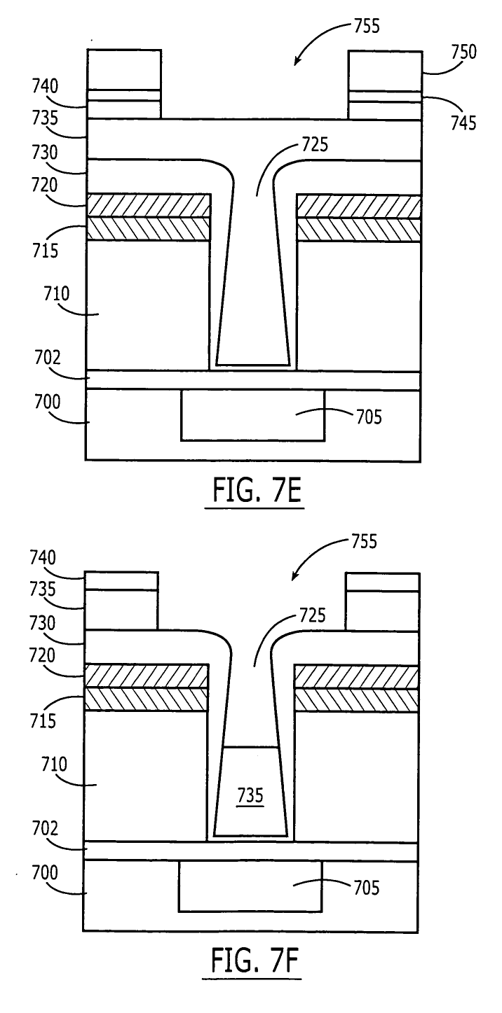

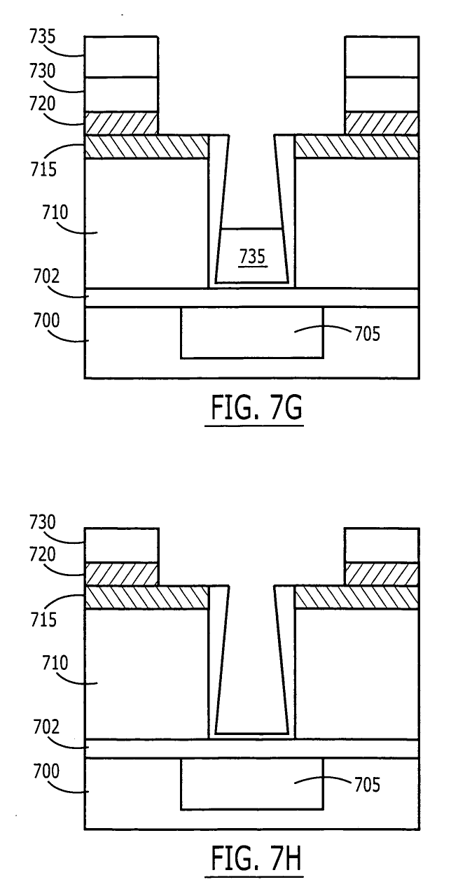

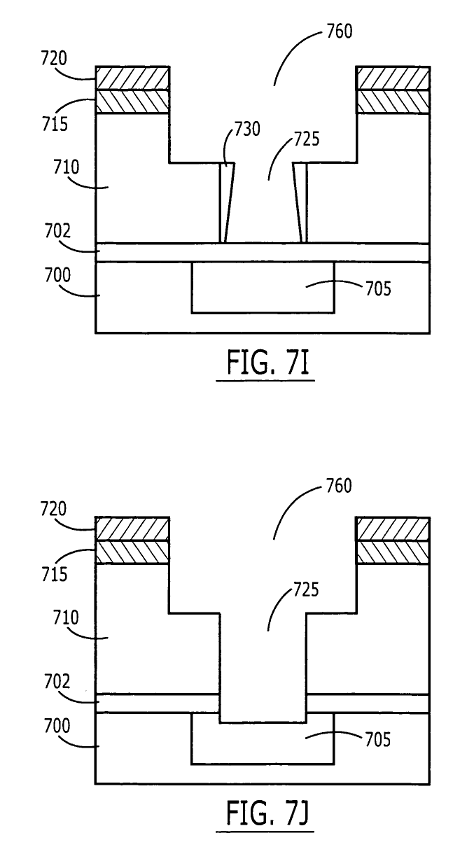

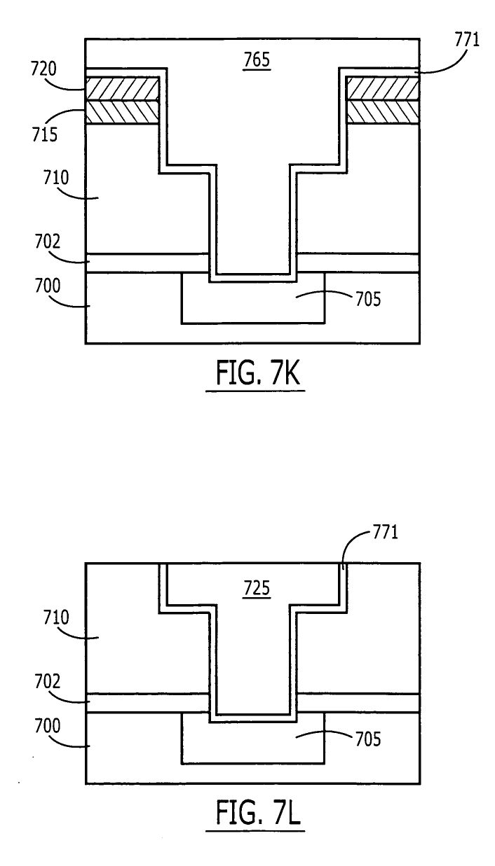

FIGS. 7A-7L are cross sectional views that illustrate methods of forming contact structures using a “via first” dual damascene process according to some embodiments of the invention. According to FIG. 7A, a lower level copper interconnect 705 is provided in a substrate 700 having a via etch stop layer 702 thereon. A low-k material 710, a first hard mask layer 715, and a second hard mask layer 720 are formed on the etch stop layer 702. A recess 725 is formed in the low-k material 710, and in first and second hard mask layers 715, 720, to provide a lower portion of a contact structure as part of a “via first” dual damascene process. In some embodiments according to the invention, the recess size at the base is about 145 nm. In some embodiments according to the invention, the low-k material 710 can be porous SiCOH, the first hard mask layer 715 can be formed of SiCOH material and the second hard mask layer 720 can be formed of TEOS material. In some embodiments according to the invention, the etch stopper layer 702 can be formed of SiCNH.

According to FIG. 7B, a protective side wall spacer 730 is formed on an upper surface of the second hard mask layer 720 and on the side walls of the recess 725 and, particularly, on side walls of the recess 725 defined by the low-k material 710. In some embodiments according to the invention, the protective side wall spacer 730 is formed of SiO₂, TEOS, SiH₄ oxide, OMCTS oxide, or the like. In some embodiments according to the invention, the protective side wall spacer 730 has an etch selectivity of about 6 relative to the first hard mask layer 715. In some embodiments according to the invention, the protective side wall spacer 730 is formed to a thickness of about 10 Angstroms to about, 500 Angstroms using chemical vapor deposition or atomic layer deposition.

According to FIG. 7C, a sacrificial material 735 is formed on an upper surface of the protective side wall spacer 730 and to fill the recess 725 and a mask oxide layer 740 is formed on the sacrificial material 735. In some embodiments according to the invention, the sacrificial material 735 can be an organic polymer. In some embodiments according to the invention, the mask oxide layer 740 can be a low temperature SiH₄ based oxide such as a material formed by a combination of SIH₄ and N₂O.

According to FIG. 7D, an antireflective coating 745 is formed on the mask oxide layer 740 and a photoresist material 750 is formed thereon and patterned to provide an opening 755 over the recess 725 filled with the sacrificial material 735 and having the protective side wall spacer 730 thereon. In some embodiments according to the invention, the photoresist material 750 can be formed of an organic polymer such as the same organic polymer that is used to form the sacrificial material 735 in the recess 725. In some embodiments according to the invention, the photoresist material 750 is different than the sacrificial material 735.

According to FIG. 7E, the mask oxide 740 is etched through the opening 755 using the photoresist material 750 as an etch mask to expose the sacrificial material 735. According to FIG. 7F, the sacrificial material 735 exposed as shown above in FIG. 7E is further etched from inside the recess 725 while the protective spacer 730 is maintained on the entire side wall of the recess 725, thereby allowing protection to the low-k material 710 during removal of the sacrificial material 735. It will be further understood that in some embodiments according to the invention, the photoresist material 750 is also removed along with the sacrificial material 735 while the protective spacer 730 is maintained on the entire side wall of the recess 725. In some embodiments according to the invention, the sacrificial material 730 and/or the photoresist material 750 are dry etched.

According to FIG. 7G, etching continues so that the portion of the protective side wall spacer 730 and the second hard mask layer 720 located outside the recess 725 are removed to expose an upper surface of the first hard mask layer 715 outside the recess 725. Accordingly, in some embodiments according to the invention, the first hard mask layer 715 and the protective side wall spacer 730 have an etch selectivity relative to one another. In other words, in some embodiments according to the invention, the protective side wall spacer 730 may be etched relatively quickly in the presence of an etchant whereas the first hard mask layer 715 is relatively little in the presence of the same etchant. In some embodiments according to the invention, the protective side wall spacer 730 has an etch selectivity of about 6 relative to the first hard mask layer 715. In some embodiments according to the invention, the etching of the protective side wall spacer 730 and the second hard mask layer 720 can be provided by dry etching using a mixture of Ar, N₂ and C₄F₈ as an etchant at a pressure of about 45 mT.

According to FIG. 7H, the sacrificial material 735 is removed from the recess 725, so the etch stopper 702 is exposed at the base of the recess 725. As described above in reference to FIG. 7F, the etching can be performed by a dry etch.

According to FIG. 7I, the second hard mask layer 720 can be used as a hardmask mask to form a trench 760 as part of an upper portion of the contact structure formed according to embodiments of the “via first” dual damascene process described herein. According to FIG. 7J, the protective side wall spacer 725 located on the side walls of the low-k material 710 inside the via portion of the contact structure is removed and the exposed portion of the etch stop layer 702 is removed to expose the underlying copper interconnect 705.

According to FIG. 7K, a copper material 765 is deposited in the via portion of the contact structure and in the trench portion of the structure thereby filling the via and trench as shown. In some embodiments according to the invention, the copper material is formed using, for example, electroplating. In particular, a seed layer may first be formed by sputtering which may be subject to the electroplating for the formation of the copper material 765. According to FIGS. 7K and 7L, the copper material 765 is planarized using CMP to provide the contact structure using the “via first” dual damascene process as described above in reference to FIGS. 7A-7K. As shown in FIG. 7K, a metal barrier layer 771 may be formed beneath the copper material 765.

As described herein, in some embodiments according to the invention, a protective side wall spacer that is formed in a recess in a low-k material is maintained while a material (such as a photoresist and/or a sacrificial material in the recess) is removed. The removal of the photoresist and/or sacrificial material can be performed by an ashing process whereby the low-k material may be damaged if the protective side wall spacer is not maintained in the recess. As described herein in greater detail, the recess can provide the lower portion of a “via first” contact structure formed using a dual damascene process. Accordingly, in some embodiments according to the invention, a trench can be formed to provide an upper part of the contact structure in the “via first” dual damascene process. The trench can be formed by using remnants of the protective spacer that are outside the recess as an etching mask. Accordingly, in some embodiments according to the invention, the material removed by an ashing process can be removed prior to formation of the trench thereby allowing the low-k material to be protected by the protective side wall spacer during the removal of the material in the ashing process (e.g., photoresist and/or sacrificial material in the via).

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed:

1. A method of forming a via using a dual damascene process comprising:
removing a material from a recess in a low-k material using an ashing process while maintaining a protective spacer on an entire side wall of the recess to cover the low-k material in the recess.

2. A method according to claim 1 wherein removing a material comprises removing a sacrificial material from the recess.

3. A method according to claim 2 wherein removing a material further comprises:
removing a photo-resist material from around the recess along with removing the sacrificial material from inside the recess.

4. A method according to claim 3 wherein the photo-resist material and the sacrificial material comprise a common material.

5. A method according to claim 4 wherein the photo-resist material and the sacrificial material comprise an organic polymer.

6. A method according to claim 1 wherein the protective spacer comprises silicon oxide.

7. A method according to claim 1 wherein removing a material from a recess further comprises:
etching the material using an etchant to expose the protective spacer inside the recess.

8. A method according to claim 1 wherein the low-k material comprises porous SiCOH.

9. A method according to claim 1 further comprising:
forming a trench over the recess;
removing the protective spacer from the side wall; and
filling the recess and the trench with copper.

10. A method of forming a via using a dual damascene process comprising:
removing a sacrificial material from a low-k material having a recess therein with a protective side wall spacer; and then
forming a trench over the recess; and
removing the side wall spacer.

11. A method according to claim 10 wherein the protective side wall spacer comprises an organic polymer.

12. A method according to claim 10 wherein removing a sacrificial material further comprises:
etching the sacrificial material using an etchant to expose the protective side wall spacer inside the recess.

13. A method according to claim 10 wherein the protective side wall spacer comprises silicon oxide.

14. A method according to claim 10 wherein the low-k material comprises porous SiCOH.

15. A method according to claim 10 wherein forming a trench comprises etching the low-k material using an etchant to form the trench.

16. A method of forming a via using a dual damascene process comprising:
forming a hard mask material on a low-k material;
forming a via in the low-k material through the hard mask material;
forming a protective side wall spacer on a side wall of the via and on the hard mask material, wherein the protective side wall spacer has an etch selectivity relative to the hard mask material;
forming a sacrificial material in the via on the protective side wall;
forming a photo-resist material on the hard mask material including an opening therein over the via;
removing the photo-resist material and the sacrificial material from inside the via while avoiding removing the protective side wall spacer from inside the via;
forming a trench over the via while maintaining a lower portion of the via having the protective side wall spacer thereon;
removing the protective side wall spacer from the lower portion of the via; and
filling the via and the trench with copper.

17. A method according to claim 16 wherein removing the photo-resist and the sacrificial material comprises removing the photo-resist material from around the recess along with removing the sacrificial material from inside the recess.

18. A method according to claim 16 wherein the photo-resist material and the sacrificial material comprise a common material.

19. A method according to claim 18 wherein the photo-resist material and the sacrificial material comprise an organic polymer.

20. A method according to claim 22 wherein the protective side wall spacer comprises silicon oxide.

21. A method according to claim 22 wherein the low-k material comprises porous SiCOH.

22. A method according to claim 22 forming a trench over the via comprises
etching the hard mask material to remove the hard mask material from an upper surface of the low-k material and a portion of the low-k material beneath the upper surface to form the trench in the low-k material while maintaining the protective spacer on a lower portion of the via.

23. A method of forming contact structures using a via-first dual damascene process comprising:
maintaining a protective spacer on an entire side wall of a recess in an low-k material during removal of a sacrificial material inside the recess.

24. A method according to claim 23 wherein maintaining a protective spacer comprises:
maintaining the protective spacer on an entire side wall of the recess in the low-k material during removal of the sacrificial material inside the recess and removal of a photo-resist material from outside the recess.

25. A method according to claim 23 wherein the protective spacer comprises silicon oxide.

26. A method according to claim 23 wherein the low-k material comprises porous SiCOH.
